(19) United States
(12) Patent Application Publication
(10) Pub. No.: US 2013/0248880 A1
(43) Pub. Date: Sep. 26, 2013

(54) SEMICONDUCTOR DEVICE AND METHOD FOR MANUFACTURING THE SAME

(71) Applicants: Keiko ARIYOSHI, Okayama-ken (JP); Takuma Suzuki, Kanagawa-ken (JP); Hiroshi Kono, Kanagawa-ken (JP); Takashi Shinohe, Kanagawa-ken (JP)

(72) Inventors: Keiko ARIYOSHI, Okayama-ken (JP); Takuma Suzuki, Kanagawa-ken (JP); Hiroshi Kono, Kanagawa-ken (JP); Takashi Shinohe, Kanagawa-ken (JP)

(73) Assignee: Kabushiki Kaisha Toshiba, Tokyo (JP)

(21) Appl. No.: 13/601,457

(22) Filed: Aug. 31, 2012

(30) Foreign Application Priority Data
Mar. 26, 2012 (JP) 2012-070391

(51) Int. Cl. H01L 29/788; H01L 29/66

(52) U.S. Cl. CPC H01L 29/7889; H01L 29/66825
USPC 257/77; 438/259

(57) ABSTRACT

According to one embodiment, a semiconductor device includes a first, a second, a third, and a fourth semiconductor region, a control electrode, a floating electrode, and an insulating film. The first region contains silicon carbide. The second region is provided on the first region and contains silicon carbide. The third region is provided on the second region and contains silicon carbide. The fourth region is provided on the third region and contains silicon carbide. The control electrode is provided in a trench formed in the fourth, the third, and the second region. The floating electrode is provided between the control electrode and a bottom surface of the trench. The insulating film is provided between the trench and the control electrode, between the trench and the floating electrode, and between the control electrode and the floating electrode.

### CROSS-REFERENCE TO RELATED APPLICATION

This application is based upon and claims the benefit of priority from the prior Japanese Patent Application No. 2012-070391, filed on Mar. 26, 2012; the entire contents of which are incorporated herein by reference.

### FIELD

Embodiments described herein relate generally to a semiconductor device and a method for manufacturing the same.

### BACKGROUND

As compared to silicon (Si), silicon carbide (SiC) has excellent physical properties; it has three 3 as large a band gap, about 10 times as large as a breakdown field strength, and about 3 times as large as a heat conductivity. By utilizing those properties, it is possible to realize a low-loss semiconductor device excellent in high-temperature performance.

Such semiconductor devices utilizing those SiC properties may include metal oxide semiconductor field effect transistors (MOSFETs) and insulated gate bipolar transistors (IGBTs). Among those device structures, a gate-electrode planar structure has merits for finer patterning and higher integration densities than the planar type, being expected to further lower the turn-on resistance.

In the properties of the semiconductor devices using SiC, improvements in breakdown voltages are important.

### BRIEF DESCRIPTION OF THE DRAWINGS

FIG. 1 is a schematic cross-sectional view illustrating a configuration of a semiconductor device according to a first embodiment;

FIGS. 2A and 2B are schematic cross-sectional views illustrating electric field relaxation states;

FIGS. 3A and 3B illustrate charge drawing;

FIGS. 4 to 8 are schematic cross-sectional views illustrating the semiconductor device manufacturing method; and

FIGS. 9A and 9B are schematic cross-sectional views illustrating examples of other semiconductor devices.

### DETAILED DESCRIPTION

In general, according to one embodiment, a semiconductor device includes a first semiconductor region, a second semiconductor region, a third semiconductor region, a fourth semiconductor region, a control electrode, a floating electrode, and an insulating film. The first semiconductor region contains silicon carbide. The second semiconductor region is provided on the first semiconductor region and contains silicon carbide of a first conductivity type. The third semiconductor region is provided on the second semiconductor region and contains silicon carbide of a second conductivity type. The fourth semiconductor region is provided on the third semiconductor region and contains silicon carbide of the first conductivity type. The control electrode is provided in a trench formed in the fourth semiconductor region, the third semiconductor region, and the second semiconductor region. The floating electrode is provided between the control electrode and a bottom surface of the trench. The insulating film is provided between the trench and the control electrode, between the trench and the floating electrode, and between the control electrode and the floating electrode.

Various embodiments will be described hereinafter with reference to the accompanying drawings.

The drawings are schematic or conceptual, so that the relationship between thickness and width of each of the components and the size ratio between the components are not always realistic. Even the same component may be denoted with different sizes or ratios in the different drawings.

In the specification and the drawings, identical reference numerals are given to identical components in examples, and detailed description on the identical components will be omitted appropriately.

In the following description, as one example, a specific example is given in which a first conductivity type is assumed to be an n type and a second conductivity type is assumed to be a p type.

Further, in the following description, the notations of n⁺, n, and n⁻ as well as p⁺, p, and p⁻ denote relative levels in impurity concentration of those conductivity types. That is, “n⁺” denotes a relatively higher impurity concentration than “n” and “n⁻” denotes a relatively lower impurity concentration than “n”. Further, “p⁺” denotes a relatively higher impurity concentration than “p” and “p⁻” denotes a relatively lower impurity concentration than “p”.

### First Embodiment

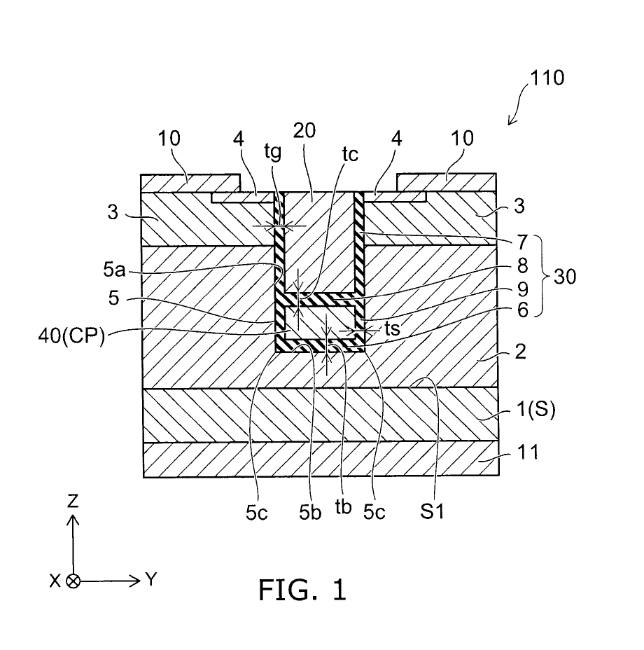

FIG. 1 is a schematic cross-sectional view illustrating a configuration of a semiconductor device according to a first embodiment.

As shown in FIG. 1, a semiconductor device 110 according to the embodiment includes a first semiconductor region 1, a second semiconductor region 2, a third semiconductor region 3, a fourth semiconductor region 4, a control electrode 20, an insulating film 30, and a floating electrode 40. The semiconductor device 110 is an MOSFET containing SiC.

The first semiconductor region 1 contains SiC of a first conductivity type (n⁺ type). The first semiconductor region 1 is formed, for example, on a substrate S containing first conductivity type (n⁺ type) SiC. The first semiconductor region 1 is, for example, a drain region of the MOSFET.

The second semiconductor region 2 is provided on the first semiconductor region 1. The second semiconductor region 2 contains first conductivity type (n⁻ type) SiC. The second semiconductor region 2 is formed on an upper surface S1 of the substrate S by, for example, epitaxial growth. The second semiconductor region 2 is a drift region of the MOSFET.

In the embodiment, it is assumed that a direction orthogonal to the upper surface S1 of the substrate S is referred to as a Z direction, one of directions orthogonal to the Z direction is referred to as an X direction, and a direction orthogonal to the Z and X directions is referred to as a Y direction. Further, it is assumed that a direction toward the second semiconductor region 2 from the substrate S is referred to as an upward direction and a direction toward the substrate S from the second semiconductor region 2 is referred to as a downward direction (lower side).

The third semiconductor region 3 is provided on the second semiconductor region 2. The third semiconductor region 3 contains SiC of the second conductivity type (p type). The third semiconductor region 3 is a p type base region of the MOSFET.

The fourth semiconductor region 4 is provided on the third semiconductor region 3. The fourth semiconductor region 4 contains SiC of the first conductivity type (n⁺ type). The fourth semiconductor region 4 is, for example, a source region of the MOSFET.

The control electrode 20 is provided in a trench 5 formed in the fourth semiconductor region 4, the third semiconductor region 3, and the second semiconductor region 2. The trench 5 is formed through the fourth semiconductor region and the third semiconductor region 3 in the Z direction to somewhere halfway through the second semiconductor region 2. The control electrode 20 is embedded in the trench 5. The control electrode 20 is a gate electrode of the MOSFET.

The insulating film 30 is provided in the trench 5. The insulating film 30 has a bottom portion insulating film 6, a gate insulating film 7, an intermediate insulating film 8, and a side portion insulating film 9. The bottom portion insulating film 6 is provided between a bottom surface 5b of the trench 5 and a floating electrode 40 to be described later. The gate insulating film 7 is provided between a side surface 5a of the trench 5 and the control electrode 20. The intermediate insulating film 8 is provided between the control electrode 20 and the floating electrode 40. The side portion insulating film 9 is provided between the side surface 5a of the trench 5 and the floating electrode 40. The gate insulating film 7 is a gate insulating film of the MOSFET.

The floating electrode 40 is provided in the trench 5. The floating electrode 40 is provided between the control electrode 20 and the bottom surface 5b of the trench 5 in the trench 5. The floating electrode 40 is separated from the control electrode 20 via the intermediate insulating film 8. The floating electrode 40 is floating electrically.

Next, a description will be given of a specific example of the semiconductor device 110 according to the first embodiment.

The substrate S on which the first semiconductor region 1 is formed contains, for example, 4H—SiC. The substrate S is an n⁺ type substrate containing an n type impurity such as nitrogen (N) at a density of about not less than 5×10¹⁸ cm⁻³ and not more than 1×10¹⁹ cm⁻³.

The upper surface S1 of the substrate S is a (0001) plane or (000-1) plane. In the embodiment, a case where the upper surface S1 is a (000-1) plane is given as an example. The second semiconductor region 2 formed on the (000-1) plane is an n⁻ type layer containing an n type impurity at a density of about not less than 5×10¹⁵ cm⁻³ and not more than 1×10¹⁷ cm⁻³.

In a portion of the surface of the second semiconductor region 2, the third semiconductor region 3 is formed which contains a p type impurity such as Al or B at a density of about not less than 1×10¹⁷ cm⁻³ and not more than 5×10¹⁸ cm⁻³. In a portion of the surface of the third semiconductor region 3, the fourth semiconductor region 4 is formed which contains an n type impurity at a density of about 1×10²⁰ cm⁻³.

Further, the trench 5 is formed from the surface of the fourth semiconductor region 4 through the third semiconductor region 3 to somewhere halfway through the second semiconductor region 2. At least one of the side surfaces 5a of the trench 5 is a (11-20) plane of the substrate S.

In the trench 5, the control electrode 20 and the floating electrode 40 are provided via the insulating film 30. The control electrode 20 and the floating electrode 40 are made of, for example, polysilicon. Besides polysilicon, the control electrode 20 may be made of TiN or TaN.

The insulating film 30 (the bottom portion insulating film 6, the gate insulating film 7, the intermediate insulating film 8, and the side portion insulating film 9) formed in the trench 5 is made of, for example, silicon oxide. The control electrode 20 is enclosed by the gate insulating film 7 and the intermediate insulating film 8 in the trench 5. The floating electrode 40 is enclosed by the intermediate insulating film 8, the side portion insulating film 9, and the bottom portion insulating film 6 in the trench 5.

A film thickness tc of the intermediate insulating film 8 that determines spacing between the floating electrode 40 and the control electrode 20 is larger than a film thickness tg of the gate insulating film 7. The film thickness tg of the gate insulating film 7 is, for example, 50 nanometers (nm). The film thickness tc of the intermediate insulating film 8 is, for example, 75 nm.

By setting the film thickness tc of the intermediate insulating film 8 larger than the film thickness tg of the gate insulating film 7, effects can be obtained to inhibit a leakage current from flowing between the control electrode 20 and the floating electrode 40 and inhibit a voltage applied to the control electrode when the semiconductor device 110 is in the on-state from fluctuating.

A film thickness tb of the bottom portion insulating film 6 that determines spacing between the floating electrode 40 and the bottom surface 5b of the trench 5 is larger than the film thickness tg of the gate insulating film 7. The film thickness tb of the bottom portion insulating film 6 is, for example, 75 nm.

By setting the film thickness tb of the bottom portion insulating film 6 larger than the film thickness tg of the gate insulating film 7, effects can be obtained to relax electric field concentration at the bottom portion of the trench.

The film thickness ts of the side portion insulating film 9 that determines spacing between the floating electrode 40 and the side surface 5a of the trench 5 is nearly equal to the film thickness tg of the gate insulating film 7. The film thickness ts of the side portion insulating film 9 is, for example, 50 nm.

A semiconductor device having a trench gate structure using SiC has a larger internal electric field than a semiconductor device having the same structure using Si and is subject to electric field concentration especially at the trench bottom portion. In the semiconductor device 110 according to the embodiment, the floating electrode 40 is provided in the trench 5 in an attempt to relax electric field concentration at the bottom surface 5b and a corner portion 5c of the trench 5, thereby, improving the breakdown voltage in the SiC device. In the embodiment, it is unnecessary to provide a plurality of trenches in each of the semiconductor devices 110 in order to improve the breakdown voltage by providing the floating electrode 40 in the trench 5.

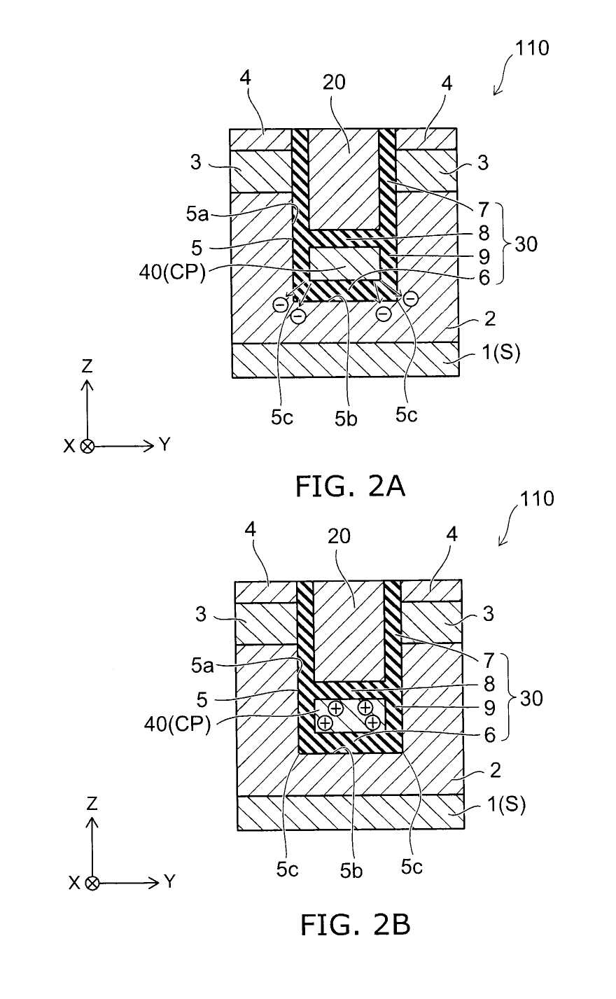

FIGS. 2A and 2B are schematic cross-sectional views illustrating electric field relaxation states.

FIG. 2A shows a state where, for example, a positive high voltage is applied to the first semiconductor region 1. FIG. 2B shows a state of charge in the floating electrode 40.

That is, as shown in FIG. 2A, if a voltage (for example, 0 volt (V)) that turns off the semiconductor device 110 is applied to the control electrode 20 and a positive high voltage Vd+ is applied to the first semiconductor region 1, a high electric field is applied to the insulating film 30.

Due to this electric field, a Fowler Nordheim (FN) tunnel current which passes through the insulating film 30 flows toward the second semiconductor region 2 from the floating electrode 40. Due to the FN tunnel current, electrons in the floating electrode 40 are released toward the second semiconductor region 2. As a result, as shown in FIG. 2B, the floating electrode 40 can function as a charged portion CP which is charged positively.

If the floating electrode 40 is charged positively, a difference in potential between the second semiconductor region 2 and the floating electrode 40 decreases. Thus, electric field concentration on the insulating film 30 in contact with the floating electrode 40 is relaxed to improve the breakdown voltage.

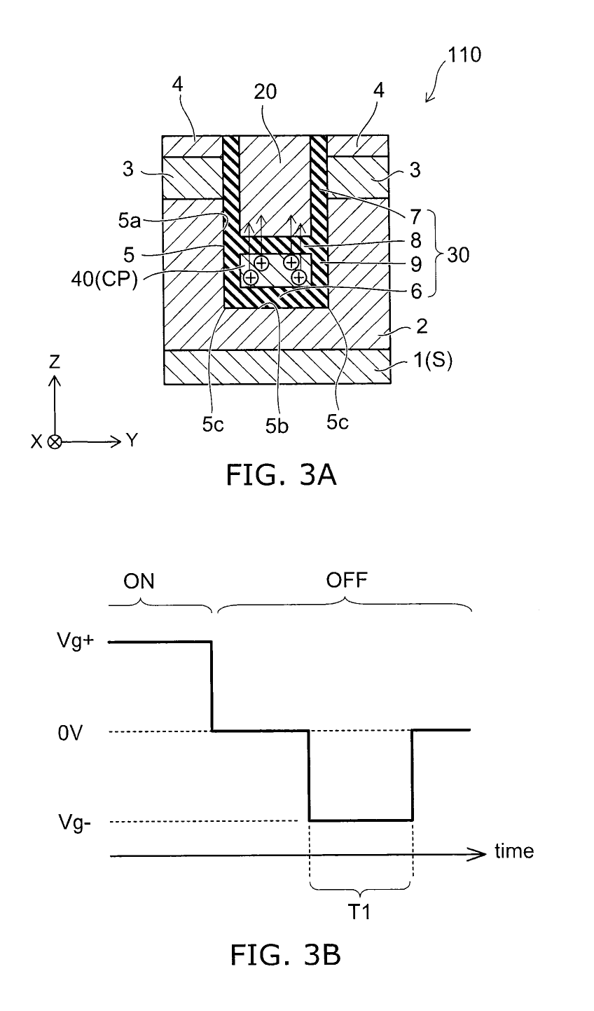

FIGS. 3A and 3B illustrate charge drawing.

FIG. 3A shows a state where charge is drawn out from the floating electrode 40. FIG. 3B shows timing that a voltage is applied to the control electrode. A horizontal axis shown in FIG. 3B gives time and its vertical axis gives a voltage applied to the control electrode 20.

As shown in FIG. 3B, if a positive voltage Vg+ in excess of a threshold voltage is applied to the control electrode 20, the semiconductor device 110 is turned on. If a voltage (for example, 0 V) not in excess of the threshold voltage is applied to the control electrode 20, the semiconductor device 110 is turned off.

If a high voltage Vd+ is applied to the first semiconductor region 1 in condition where the semiconductor device 110 is in the off-state, positive charge is accumulated in the floating electrode 40 as shown in FIG. 2B. In such a manner, electric field concentration on the bottom surface of the trench 5 is relaxed to improve the breakdown voltage.

Even in the state where positive charge is accumulated in the floating electrode 40, it is no problem as long as the properties of the semiconductor device 110 are not affected, for example, the threshold voltage is not fluctuated. If it is necessary to restore an original potential of the floating electrode 40 because the charge accumulated in the floating electrode 40 is drawn out, a negative voltage Vg− is applied to the control electrode 20 as shown in FIG. 3B. If the negative voltage Vg− is applied to the control electrode 20, the charge accumulated in the floating electrode 40 is drawn out toward the control electrode 20. Thus, the original potential of the floating electrode 40 is restored.

### Second Embodiment

Next, a description will be given to a method of manufacturing a semiconductor device 110 as a second embodiment.

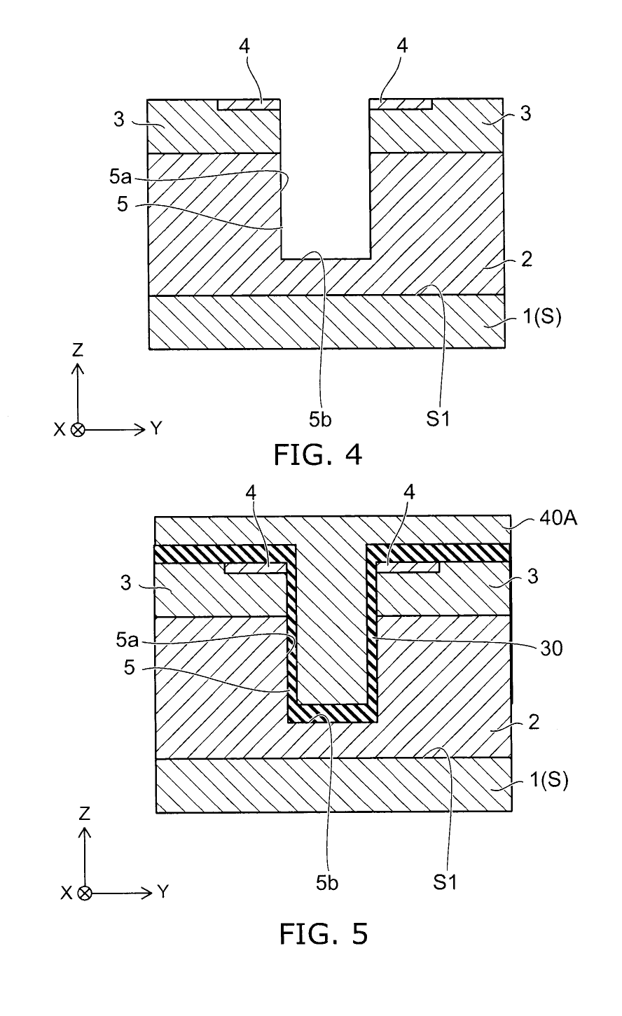

FIGS. 4 to 8 are schematic cross-sectional views illustrating the semiconductor device manufacturing method.

First, as shown in FIG. 4, a low-resistance and 4H—SiC made substrate S is prepared which contains phosphorus or N at a density of about 1×10¹⁹ cm⁻³ as an n type impurity and has a thickness of, for example, 300 micrometers (μm) and a hexagonal crystal-based crystal lattice. The substrate S includes the first semiconductor region 1.

On the (000-1) plane of the SiC-made substrate S, the second semiconductor region 2 is grown which contains, for example, N at an impurity concentration of about 5×10¹⁵ cm⁻³ as an n type impurity by, for example, epitaxial growth and has a thickness of, for example, 10 μm.

Next, for example, aluminum (Al) ions are injected as a p type impurity in a surface of the second semiconductor region 2 by using appropriate masks, thereby forming a third semiconductor region 3. Next, for example, N ions are injected as an n type impurity in a surface of the third semiconductor region 3 by using appropriate masks, thereby forming a fourth 3o semiconductor region 4. Then, heat treatment at a temperature of, for example, about 1600° C. is conducted to activate the impurity.

Next, anisotropic etching is performed to form a trench 5 having a depth which reaches the second semiconductor region 2 via the third semiconductor region 3 from the surface of the fourth semiconductor region 4. At least one of side surfaces 5a of the trench 5 is a (11-20) plane of the substrate S. After the etching, preferably, heat treatment is conducted to flatten inner surfaces (side surface 5a and bottom surface 5b) of the trench 5. Further, the bottom surface 5b of the trench 5 may be shaped like a curve by performing etching or heat treatment.

Next, as shown in FIG. 5, a SiO₂ film having a film thickness of about not less than 30 nanometers (nm) and not more than 100 nm is formed using thermal oxidation, chemical vapor deposition (CVD), or atomic layer deposition (ALD). The SiO₂ film provides an insulating film 30. In this case, preferably a film thickness t1 of the SiO₂ film (bottom portion insulating film 6) on a bottom portion of the trench 5 is larger than a film thickness t2 of the SiO₂ film (gate insulating film 7) on the side surface of the trench 5.

Such SiO₂ films having the different film thicknesses in the trench 5 can be realized by utilizing an anisotropic film forming method or utilizing a fact that the oxidization rate is different with the different plane direction in the trench 5. Further, an aluminum oxide film (Al₂O₃ film) may be formed in place of the SiO₂ film by using CVD, ALD, or physical vapor deposition (PVD).

Next, a floating electrode material 40A is embedded in the trench 5. The floating electrode material 40A is, for example, polysilicon.

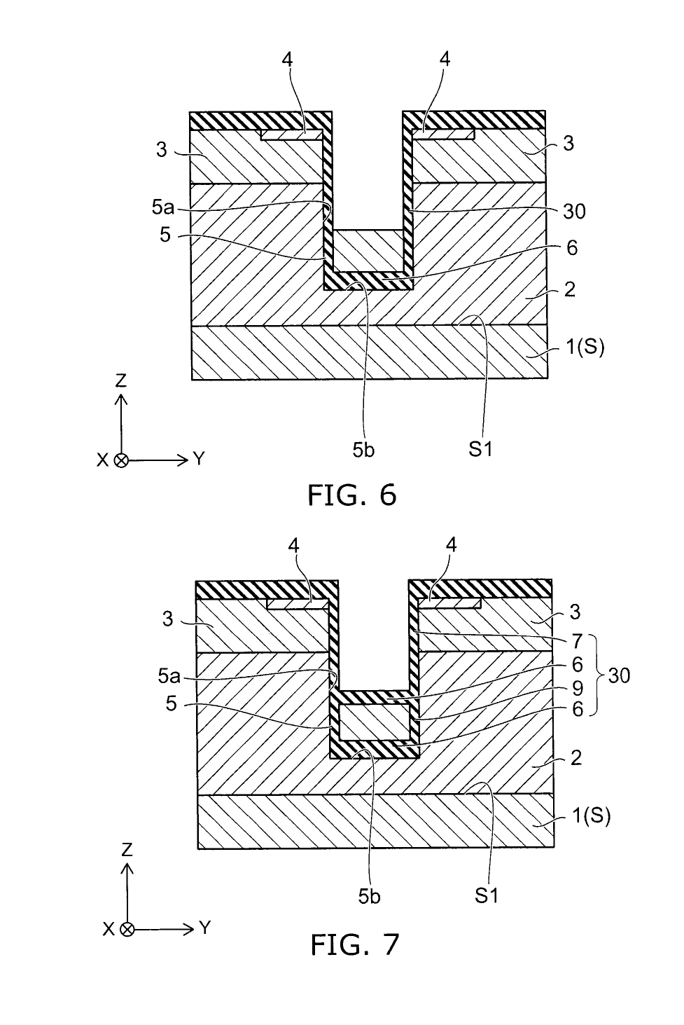

Next, as shown in FIG. 6, the floating electrode material 40A is etched back. By the etch back processing, the floating electrode material 40A retreats from an opening of the trench 5. The floating electrode material 40A left after the etch back processing provides a floating electrode 40.

Next, as shown in FIG. 7, an intermediate insulating film 8 of an insulating film 30 is formed on an exposed surface of the floating electrode 40. The intermediate insulating film 8 is formed by, for example, thermal oxidization. If the gate insulating film 7 contains silicon oxide and the floating electrode 40 contains polysilicon, the silicon oxide film is formed on the polysilicon-exposed upper surface of the floating electrode 40 more than on the surface of the gate oxide film 7. If the thermal oxidization conditions are selected, the silicon oxide film is formed on the upper surface of the floating electrode 40 without changing the film thickness of the gate oxide film 7 mostly. The silicon oxide film formed on the upper surface of the floating electrode 40 provides the intermediate insulating film 8. The intermediate insulating film 8 is thus formed to thereby form the floating electrode 40 enclosed by the insulating film 30 in the trench 5.

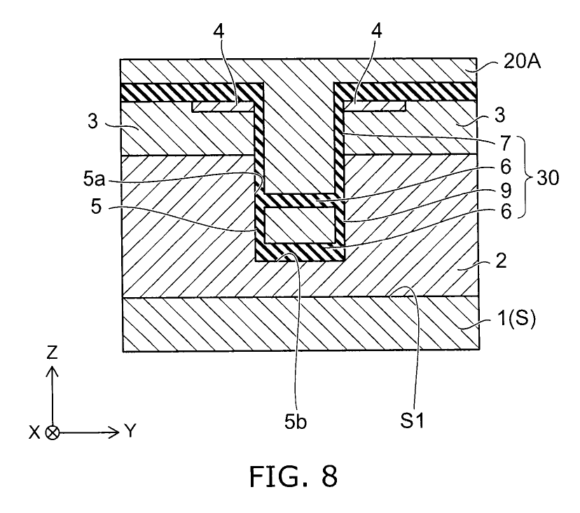

Next, as shown in FIG. 8, a control electrode material 20A is embedded on the intermediate insulating film 8 in the trench 5. The control electrode material 20A is, for example, polysilicon. After being formed, the control electrode material 20A is patterned into a control electrode 20. Then, by using a publicly known technology, electrode films are formed and patterned into a first electrode 10 and a second electrode 11 such as shown in FIG. 1. In such a manner, the semiconductor device 110 is finished.

By such a manufacturing method, for each of the semiconductor devices 110, one trench 5 is provided to provide the floating electrode 40 in the trench 5. Therefore, the semiconductor device 110 having an improved breakdown voltage is provided without providing a plurality of trenches for each of the semiconductor devices.

### Third Embodiment

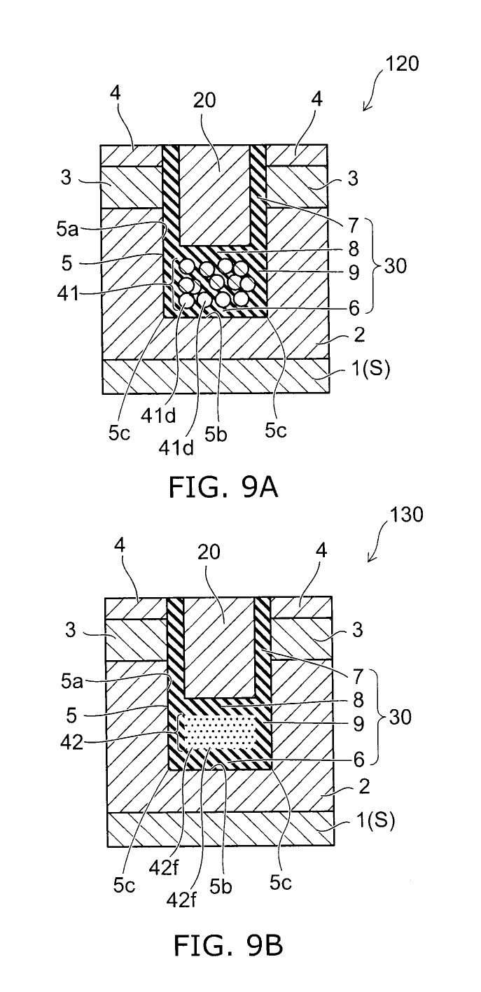

FIGS. 9A and 9B are schematic cross-sectional views illustrating examples of other semiconductor devices.

FIG. 9A shows an example of a semiconductor device 120 using a silicon dot. FIG. 9B shows an example of a semiconductor device 130 using defects. In both of the figures, only a peripheral portion of a control electrode 20 in a trench 5 is shown.

In a semiconductor device 120 shown in FIG. 9A, a silicon dot portions 41 is provided in place of the floating electrode 40 of the semiconductor device 110 shown in FIG. 1. The silicon dot portion 41 is provided between a control electrode 20 and a bottom surface 5b of a trench 5. The silicon dot portion 41 is provided in a bottom portion insulating film 6 of an insulating film 30.

The silicon dot portion 41 includes silicon dots 41d, which are microcrystals of silicon. The silicon dots 41d are each a ball-shaped microcrystal of silicon having a diameter of about several nanometers. In the silicon dot portion 41, a plurality of the silicon dots 41 are disposed three-dimensionally.

The silicon dot portion 41 including such silicon dots 41d have almost the same effects as those by the floating electrode 40 of the semiconductor device 110 shown in FIG. 1. That is, if a voltage (for example, 0 volt (V)) that turns off the semiconductor device 120 is applied to the control electrode 20 and a positive high voltage Vd+ is applied to the first semiconductor region 1, positive charge is accumulated in the silicon dots 41 by a high electric field applied to the insulating film 30, thereby charging the silicon dot portion 41 positively. That is, the silicon dot portion 41d functions as a charged portion CP. Thus, electric field concentration on the insulation film 30 in contact with the silicon dot portion 41 is relaxed to improve the breakdown voltage.

In the semiconductor device 130 shown in FIG. 9B, a defective portion 42 is provided in place of the floating electrode 40 of the semiconductor device 110 shown in FIG. 1. The defective portion 42 is provided between the control electrode 20 and the bottom surface 5b of the trench 5. The defective portion 42 is provided in the bottom portion insulating film 6 of the insulating film 30. The defective portion 42 has defects (crystal defects 42f) of crystals contained in the bottom portion insulating film 6.

The defective portion 42 containing such crystal defects 42f functions as the floating electrode 40 of the semiconductor device 110 shown in FIG. 1. That is, if a voltage (for example, 0 volt (V)) that turns off the semiconductor device 120 is applied to the control electrode 20 and the positive high voltage Vd+ is applied to the first semiconductor region 1, positive charge is accumulated in the crystal defects 42f by a high electric field applied to the insulating film 30, thereby charging the defective portion 42 positively. That is, the defective portion 42 functions as the charged portion CP. Thus, electric field concentration on the insulating film 30 in contact with the defective portion 42 to improve the breakdown voltage.

As described hereinabove, the semiconductor device and the method of manufacturing the same according to the embodiment can improve the breakdown voltage of the semiconductor device.

Although the embodiments and the variants have been described, the invention is not limited to those examples. For example, appropriate additions, deletions, and design modifications of the components of the above embodiments and variants as well as appropriate combinations of their features by those skilled in the art are covered by the scope of the invention as long as they include the gist of the invention.

For example, although the above embodiments and variants have been described on the assumption that the first conductivity type is n and the second conductivity type is p, the invention can be carried out also if the first conductivity type is assumed to be p and the second conductivity type is assumed to be n. Further, although the above embodiments have been described by assuming an n type MOSFET using electrons as its carrier, it is also possible to form the construction of the above embodiments on a substrate containing a p type impurity and apply it to an n type IGBT. Further, the above embodiments can be applied also to a p type MOSFET and a p type IGBT that use holes as the carrier.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region containing silicon carbide;
a second semiconductor region provided on the first semiconductor region, the second semiconductor region containing silicon carbide of a first conductivity type;
a third semiconductor region provided on the second semiconductor region, the third semiconductor region containing silicon carbide of a second conductivity type;
a fourth semiconductor region provided on the third semiconductor region, the fourth semiconductor region containing silicon carbide of the first conductivity type;
a control electrode provided in a trench, the trench formed in the fourth semiconductor region, the third semiconductor region, and the second semiconductor region;
a floating electrode provided between the control electrode and a bottom surface of the trench; and
an insulating film provided between the trench and the control electrode, between the trench and the floating electrode, and between the control electrode and the floating electrode.

2. The semiconductor device according to claim 1, wherein the insulating film includes:
a gate insulating film provided between a side surface of the trench and the control electrode;
a bottom portion insulating film provided between a bottom surface of the trench and the floating electrode;
an intermediate insulating film provided between the control electrode and the floating electrode; and
a side portion insulating film provided between the side surface of the trench and the floating electrode.

3. The semiconductor device according to claim 2, wherein a film thickness of the intermediate insulating film is larger than that of the gate insulating film.

4. The semiconductor device according to claim 2, wherein a film thickness of the bottom portion insulating film is larger than that of the gate insulating film.

5. The semiconductor device according to claim 2, wherein a film thickness of the side portion insulating film is equal to that of the gate insulating film.

6. The semiconductor device according to claim 1, wherein the control electrode and the floating electrode contain polysilicon.

7. The semiconductor device according to claim 1, wherein the insulating film contains silicon oxide.

8. A semiconductor device comprising:
a first semiconductor region containing silicon carbide;
a second semiconductor region provided on the first semiconductor region, the second semiconductor region containing silicon carbide of a first conductivity type;
a third semiconductor region provided on the second semiconductor region, the third semiconductor region containing silicon carbide of a second conductivity type;
a fourth semiconductor region provided on the third semiconductor region, the fourth semiconductor region containing silicon carbide of the first conductivity type;
a control electrode provided in a trench, the trench formed in the fourth semiconductor region, the third semiconductor region, and the second semiconductor region;
a charged portion provided between the control electrode and a bottom surface of the trench; and
an insulating film provided between the trench and the control electrode, between the trench and the charged portion, and between the control electrode and the charged portion.

9. The semiconductor device according to claim 8, wherein the charged portion is a floating electrode.

10. The semiconductor device according to claim 8, wherein the charged portion includes silicon dots.

11. The semiconductor device according to claim 8, wherein the charged portion contains crystal defects of the insulating film.

12. The semiconductor device according to claim 8, wherein the insulating film includes:
a gate insulating film provided between a side surface of the trench and the control electrode;
a bottom portion insulating film provided between a bottom surface of the trench and the floating electrode;
an intermediate insulating film provided between the control electrode and the floating electrode; and
a side portion insulating film provided between the side surface of the trench and the floating electrode.

13. The semiconductor device according to claim 12, wherein a film thickness of the intermediate insulating film is larger than that of the gate insulating film.

14. The semiconductor device according to claim 12, wherein a film thickness of the bottom portion insulating film is larger than that of the gate insulating film.

15. A semiconductor device manufacturing method comprising:
forming a second semiconductor region containing silicon carbide of a first conductivity type on a first semiconductor region containing silicon carbide;
forming a third semiconductor region containing silicon carbide of a second conductivity type on the second semiconductor region;
forming a fourth semiconductor region containing silicon carbide of the first conductivity type on the third semiconductor region;
forming a trench in the fourth semiconductor region, the third semiconductor region, and the second semiconductor region;
forming an insulating film on a side surface and a bottom surface of the trench;
forming a floating electrode in contact with the insulating film in the trench;
forming an intermediate insulating film on the floating electrode; and
forming a control electrode provided on the intermediate insulating film in the trench, the control electrode contacting with a gate insulating film, the gate insulating film being a portion of the insulating film contacting with the third semiconductor region.

16. The method according to claim 15, wherein:
the floating electrode contains polysilicon; and
the formation of the intermediate insulating film includes oxidizing a surface of the polysilicon contained in the floating electrode by heat treatment.

17. The method according to claim 15, wherein the formation of the intermediate insulation film includes a forming the intermediate insulating film, a film thickness of the intermediate insulating film being larger than that of the gate insulating film.

18. The method according to claim 15, wherein the formation of the insulation film includes a forming the insulating film formed on the bottom surface of the trench, a film thickness of the insulating film being larger than that of the gate insulating film.

19. The method according to claim 15, wherein the control electrode and the floating electrode contain polysilicon.

20. The method according to claim 15, wherein the insulating film contains silicon oxide.
